(19) United States
(12) Patent Application Publication
(10) Pub. No.: US 2023/0088307 A1
(43) Pub. Date: Mar. 23, 2023

(54) Hierarchical Building and Conditioning of Geological Models with Machine Learning Parameterized Templates and Methods for Using the Same

(71) Applicant: ExxonMobil Upstream Research Company, Spring, TX (US)

(72) Inventors: Fahim FOROUZANFAR, Spring, TX (US); Mulin CHENG, Spring, TX (US); Matthias G. IMHOF, Katy, TX (US); Ratnanabha SAIN, Houston, TX (US); Matthew W. HARRIS, Providence, UT (US); Amr S. EL-BAKRY, Houston, TX (US); Xiao-Hui WU, Sugar Land, TX (US)

(21) Appl. No.: 17/756,278

(22) PCT Filed: Nov. 4, 2020
(86) PCT No.: PCT/US2020/070747

§ 371 Date: May 20, 2022

Related U.S. Application Data
(60) Provisional application No. 62/951,091, filed on Dec. 20, 2019.

(51) Int. Cl. G06F 30/13

(52) U.S. Cl. CPC G06F 30/13

(57) ABSTRACT

A hierarchical conditioning methodology for building and conditioning a geological model is disclosed. In particular, the hierarchical conditioning may include separate levels of conditioning of template instances using larger-scale data (such as conditioning using large-scale data and conditioning using medium-scale data) and using smaller-scale data (such as fine-scale data). Further, one or more templates, to be instantiated to generate the geological bodies in the model, may be selected from currently available templates and/or machine-learned templates. For example, the templates may be generated using unsupervised or supervised learning to re-parameterize the functional form parameters, or may be generated using statistical generative modeling.

### CROSS REFERENCE TO RELATED APPLICATION

This application claims the benefit of priority of U.S. Provisional Application Ser. No. 62/951,091 filed Dec. 20, 2019, the disclosure of which is incorporated herein by reference in its entirety.

### TECHNICAL FIELD OF THE INVENTION

This disclosure relates generally to the field of geophysical prospecting for hydrocarbon management and related data processing. Specifically, exemplary implementations relate to methods and apparatus for generating geological models (such as reservoir models) and for generating templates for use in generating geological models.

### BACKGROUND OF THE INVENTION

This section is intended to introduce various aspects of the art, which may be associated with exemplary embodiments of the present disclosure. This discussion is believed to assist in providing a framework to facilitate a better understanding of particular aspects of the present disclosure. Accordingly, it should be understood that this section should be read in this light, and not necessarily as admissions of prior art.

The upstream oil and gas industry explores and extracts hydrocarbons in geological reservoirs which are typically found thousands of meters below the Earth's surface. Various types of geophysical and geological data are available to characterize the subsurface, including seismic data, well logs, petrophysical data, and geomechanical data. In addition, various geological concepts, including environment of depositions (e.g., channel or turbidities complexes, etc.) are available. Further, various reservoir stratigraphic configurations, such as the number of channels, channel thicknesses, etc., may be inferred.

The geophysical data, the geological concepts, and the reservoir stratigraphic configurations may be used to generate a geological model, such as a reservoir model, or interpret one or more stratigraphic features. For example, geological modeling may build 3D models to mimic both the structural geometry (e.g., the horizon, faults, etc.) and the petrophysical properties (e.g., any one, any combination, or all of the lithology, porosity, water saturation, permeability and density) of the subsurface. In turn, the geological model may be used to run flow simulations, forecast future hydrocarbon production and ultimate recovery, and design well development plans. In this regard, geological modeling (and stratigraphic interpretation) may involve constructing a digital representation of hydrocarbon reservoirs or prospects that are geologically consistent with all available information.

### SUMMARY OF THE INVENTION

A computer-implemented method for generating one or more a geological models for a subsurface is disclosed. The method includes: for a defined volume of the subsurface: generating template instances for the defined volume; conditioning the template instances based on larger-scale data; and separately conditioning the template instances based on smaller-scale data.

A computer-implemented method for generating and using a complex template is also disclosed. The method includes: accessing one or more geological constraints; parameterizing, using the one or more geological constraints, a template in order to generate the complex template that is geologically feasible; and using the complex template in order to generate a reservoir model.

### DESCRIPTION OF THE FIGURES

The present application is further described in the detailed description which follows, in reference to the noted plurality of drawings by way of non-limiting examples of exemplary implementations, in which like reference numerals represent similar parts throughout the several views of the drawings. In this regard, the appended drawings illustrate only exemplary implementations and are therefore not to be considered limiting of scope, for the disclosure may admit to other equally effective embodiments and applications.

FIG. 1 is a flow diagram of an example hierarchical conditioning methodology for building and conditioning a geological model.

FIG. 2A is a depiction of the resolution of information from core, log, seismic and production data compared to the resolution of model building blocks.

FIG. 2B is a depiction of a lobe, such as a basin floor fan lobe.

FIG. 2C is a depiction of a lobe complex, such as a basin floor fan lobe complex.

FIG. 2D is a depiction of a lobe complex set, such as a basin floor fan lobe complex set.

FIG. 3A is a cross-section depiction of the lobes, lobe complexes, and lobe complex sets of a reservoir.

FIG. 3B is a cross-section depiction of reservoir model zones divided into independent sub-zones with the contour of the lobe/channel complex templates being deformed based on the data.

FIG. 3C is a cross-section depiction of reservoir model zones divided into independent sub-zones with both the contour of the lobe/channel complex templates and an interior (such as interior lobes) being deformed based on the data.

FIG. 4A is a block diagram of lobe/channel complex template parametrization of large-scale features using an auto-encoder with unsupervised learning.

FIG. 4B is a block diagram of lobe/channel complex template parametrization of large-scale features using an auto-encoder with supervised learning.

FIG. 5A is a block diagram of lobe/channel complex template parametrization by a statistical generative model.

FIG. 5B is a block diagram of lobe/channel complex template parametrization by generative adversarial networks (GANs).

FIG. 6 is a diagram of an exemplary computer system that may be utilized to implement the methods described herein.

### DETAILED DESCRIPTION OF THE INVENTION

The methods, devices, systems, and other features discussed below may be embodied in a number of different forms. Not all of the depicted components may be required, however, and some implementations may include additional, different, or fewer components from those expressly described in this disclosure. Variations in the arrangement and type of the components may be made without departing from the spirit or scope of the claims as set forth herein. Further, variations in the processes described, including the addition, deletion, or rearranging and order of logical operations, may be made without departing from the spirit or scope of the claims as set forth herein.

It is to be understood that the present disclosure is not limited to particular devices or methods, which may, of course, vary. It is also to be understood that the terminology used herein is for the purpose of describing particular embodiments only, and is not intended to be limiting. As used herein, the singular forms “a,” “an,” and “the” include singular and plural referents unless the content clearly dictates otherwise. Furthermore, the words “can” and “may” are used throughout this application in a permissive sense (i.e., having the potential to, being able to), not in a mandatory sense (i.e., must). The term “include,” and derivations thereof, mean “including, but not limited to.” The term “coupled” means directly or indirectly connected. The word “exemplary” is used herein to mean “serving as an example, instance, or illustration.” Any aspect described herein as “exemplary” is not necessarily to be construed as preferred or advantageous over other aspects. The term “uniform” means substantially equal for each sub-element, within about ±10% variation.

The term “seismic data” as used herein broadly means any data received and/or recorded as part of the seismic surveying and interpretation process, including displacement, velocity and/or acceleration, pressure and/or rotation, wave reflection, and/or refraction data. “Seismic data” is also intended to include any data (e.g., seismic image, migration image, reverse-time migration image, pre-stack image, partially-stack image, full-stack image, post-stack image or seismic attribute image) or interpretation quantities, including geophysical properties such as one or more of: elastic properties (e.g., P and/or S wave velocity, P-Impedance, S-Impedance, density, attenuation, anisotropy and the like); and porosity, permeability or the like, that the ordinarily skilled artisan at the time of this disclosure will recognize may be inferred or otherwise derived from such data received and/or recorded as part of the seismic surveying and interpretation process. Thus, this disclosure may at times refer to “seismic data and/or data derived therefrom,” or equivalently simply to “seismic data.” Both terms are intended to include both measured/recorded seismic data and such derived data, unless the context clearly indicates that only one or the other is intended. “Seismic data” may also include data derived from traditional seismic (i.e., acoustic) data sets in conjunction with other geophysical data, including, for example, gravity plus seismic; gravity plus electromagnetic plus seismic data, etc. For example, joint-inversion utilizes multiple geophysical data types.

The terms “velocity model,” “density model,” “physical property model,” or other similar terms as used herein refer to a numerical representation of parameters for subsurface regions. Generally, the numerical representation includes an array of numbers, typically a 2-D or 3-D array, where each number, which may be called a “model parameter,” is a value of velocity, density, or another physical property in a cell, where a subsurface region has been conceptually divided into discrete cells for computational purposes. For example, the spatial distribution of velocity may be modeled using constant-velocity units (layers) through which ray paths obeying Snell's law can be traced. A 3-D geologic model (particularly a model represented in image form) may be represented in volume elements (voxels), in a similar way that a photograph (or 2-D geologic model) is represented by picture elements (pixels). Such numerical representations may be shape-based or functional forms in addition to, or in lieu of, cell-based numerical representations.

Subsurface model is a numerical, spatial representation of a specified region in the subsurface.

Geologic model is a subsurface model that is aligned with specified faults and specified horizons.

Reservoir model is a geologic model where a plurality of locations have assigned properties including rock type, environment of deposition (EoD), subtypes of EoD (sub-EoD), porosity, permeability, fluid saturations, etc.

For the purpose of the present disclosure, subsurface model, geologic model, and reservoir model are used interchangeably unless denoted otherwise.

Stratigraphic model is a spatial representation of the sequences of sediment and rocks (rock types) in the subsurface.

Structural model or framework results from structural analysis of reservoir based on the interpretation of 2D or 3D seismic images. For examples, the reservoir framework comprises horizons, faults and surfaces inferred from seismic at a reservoir section.

Conditioning data refers a collection of data or dataset to constrain, infer or determine one or more reservoir or stratigraphic models. Conditioning data might include geophysical models, petrophysical data, seismic images (e.g., fully-stacked, partially-stacked or pre-stack migration images), well log data, production data and structural framework. In this regard, conditioning geological models may comprise matching one or both of the structural geometry (such as horizon, faults, etc.) and the properties (e.g., interpreted or measured properties). As discussed further below, the conditioning process, which is executed on a computer, may be performed sequentially (e.g., matching geometrical information first and thereafter the properties) or simultaneously (e.g., matching both geometrical information and the properties concurrently). Conditioning may be performed sequentially, e.g. bottom-up, left-to-right, or east-to-west; or globally or simultaneously by matching information from a plurality of locations and updating a plurality of locations or parameters simultaneously.

Various geological bodies are contemplated. In particular, different depositional environments may result in different types of geological bodies. In turn, one or more templates may be generated for the different geological bodies. In this way, the template comprises a method to put a stratigraphic configuration, e.g., a fluvial depositional environment with braided channels, anastomosing channels, meandering channels, and overbank deposits; a deep water environment with distributed or confined channels, lobes, spills, and overbank deposits; a shallow water environment with depositional endmembers of a tidal-dominated delta, a fluvial-dominated delta, a current-dominated delta, containing channels, beaches, bars, marshes, dunes, tidal flats, lagoons, and barrier islands; Aeolian environments with sand dunes; playa environments with salt lakes, evaporites, or dunes; lake environments with lake deposits, mud slides, and marshes; alluvial fan environments with mud slides, landslides, and alluvial fans; carbonate environments with reefs, beaches, platforms and many elements already described; or another geologic configuration into a geologic model. In one preferred embodiment, a template is formed from mathematical equations.

For example, the geological body may comprise channels/lobes, channels, lobes, or the like. In this regard, any discussion regarding channels/lobes, may be applied to a geological body including channels/lobes, channels, lobes, or any other type of geological body. In turn, one or more templates may be generated for the different geological bodies. In this way, the template comprises a method to put a stratigraphic configuration, e.g., a channel, a lobe, a carbonate reef, a tidal-dominated delta, a fluvial-dominated delta, a current-dominated delta, or another geologic configuration into a geologic model. In one preferred embodiment, a template is formed from mathematical equations. Further, in one preferred embodiment, the template is instantiated by specification of parameters. In another embodiment, a (larger-scale) template is formed using a set of (smaller-scale) templates. In yet another embodiment, the template is learned from provided data samples.

Machine learning is a method of data analysis to build mathematical models based on sample data, known as training data, in order to make predictions and or decisions without being explicitly programmed to perform the tasks.

Machine learning model is the mathematical representation of a process, function, distribution or measures, which includes parameters determined through a training procedure.

Generative network model (also referred as a generative network to avoid the ambiguity with subsurface models) is an artificial network that seeks to learn/model the true distribution of a dataset giving it the ability to generate new outputs that fit the learned distribution that may not have been included in the provided sample data

Parameters of (generative or discriminator) network are weights of the neural network, which may be determined through training process.

Training (machine learning) is typically an iterative process of adjusting the parameters of a neural network to minimize a loss function which may be based on an analytical function (e.g., binary cross entropy) or based on a neural network (e.g., discriminator).

Objective function (a more general term for loss function or misfit) is a measure of the performance of a machine learning model on the training data (e.g., binary-cross entropy), and the training process seeks to either minimize or maximize the value of this function.

Adversarial training process for generative networks is a training process where the overall objective function that is being minimized or maximized includes a term related to the objective function of an adversary, also termed a discriminator. In this process both the generator and discriminator are typically trained alongside each other.

Generative Adversarial Network (GAN) is an artificial network system including generator (or interpreter) and discriminator network used for training the generative network model.

As used herein, “hydrocarbon management” or “managing hydrocarbons” includes any one or more of the following: hydrocarbon extraction; hydrocarbon production, (e.g., drilling a well and prospecting for, and/or producing, hydrocarbons using the well; and/or, causing a well to be drilled, e.g., to prospect for hydrocarbons); hydrocarbon exploration; identifying potential hydrocarbon-bearing formations; characterizing hydrocarbon-bearing formations; identifying well locations; determining well injection rates; determining well extraction rates; identifying reservoir connectivity; acquiring, disposing of, and/or abandoning hydrocarbon resources; reviewing prior hydrocarbon management decisions; and any other hydrocarbon-related acts or activities, such activities typically taking place with respect to a subsurface formation. The aforementioned broadly include not only the acts themselves (e.g., extraction, production, drilling a well, etc.), but also or instead the direction and/or causation of such acts (e.g., causing hydrocarbons to be extracted, causing hydrocarbons to be produced, causing a well to be drilled, causing the prospecting of hydrocarbons, etc.). Hydrocarbon management may include reservoir surveillance and/or geophysical optimization. For example, reservoir surveillance data may include, well production rates (how much water, oil, or gas is extracted over time), well injection rates (how much water or CO₂ is injected over time), well pressure history, and time-lapse geophysical data. As another example, geophysical optimization may include a variety of methods geared to find an optimum model (and/or a series of models which orbit the optimum model) that is consistent with observed/measured geophysical data and geologic experience, process, and/or observation.

As used herein, “obtaining” data generally refers to any method or combination of methods of acquiring, collecting, or accessing data, including, for example, directly measuring or sensing a physical property, receiving transmitted data, selecting data from a group of physical sensors, identifying data in a data record, and retrieving data from one or more data libraries.

As used herein, terms such as “continual” and “continuous” generally refer to processes which occur repeatedly over time independent of an external trigger to instigate subsequent repetitions. In some instances, continual processes may repeat in real time, having minimal periods of inactivity between repetitions. In some instances, periods of inactivity may be inherent in the continual process.

If there is any conflict in the usages of a word or term in this specification and one or more patent or other documents that may be incorporated herein by reference, the definitions that are consistent with this specification should be adopted for the purposes of understanding this disclosure.

Deep neural networks have been utilized for parametrization and modeling of reservoirs. However, these types of solutions attempt to parameterize and construct the reservoir model as a whole, which makes the practical application of such methods for an entire reservoir model, with potentially millions of grid cells, questionable due to resolution and neural network training difficulties. In particular, one may seek to model at the architectural (e.g., lobe/channel) level. However, modeling at the architectural element level may be difficult because of the following: (1) it may be difficult to enforce higher-order patterns (e.g., progradation) associated with the large-scale features; (2) there are a large number of modeling parameters if many lobes are present; and (3) it may be difficult to update highly correlated parameters of elemental templates while maintaining geologic realism.

In one or some embodiments, a hierarchical conditioning methodology is used in order to build and condition one or more geological models (such as one or more reservoir models). In one or some embodiments, a single geological model is built for a single subsurface volume. Alternatively, multiple geological models (such as multiple reservoir models) are built for a single subsurface volume. For example, the different geological models may be generated as follows: (1) the different geological models result from different solutions of the same settings of the conditioning problem (e.g., the same parameters to the problem are used to generate the different geological models; however, the solutions differ because of different template instantiations); (2) the different geological models are generated based on different parameters; or (3) the different geological models may be based on different thickness functions.

A section of a subsurface, such as a reservoir, may have a fractal or scale-invariant structure in that the structure itself may be characterized by self-similarity (e.g., sections within the subsurface possesses a configurational motif that is repeated if the scale changes). For example, different scales/levels, such as at the lobe/channel scale (or lobe/channel level), the lobe/channel complex scale (or lobe/channel complex level), and the lobe/channel complex set scale (or lobe/channel complex set level), have similarities. In this regard, iterative hierarchical conditioning may take advantage of the fractal structure of the subsurface. The fractal structure is merely one example of a self-similar structure. In that regard, any discussion herein regarding the fractal structure may be applied to any other type of self-similar structure.

Further, the geology may be defined by a hierarchy with multiple levels. For example, one such hierarchy may be defined, from lower to higher levels (such as from lowest to highest levels), at the lobe/channel level (which comprises a plurality of lobes/channel), the lobe/channel complex level (which comprises a plurality of lobe/channel complexes, each of the plurality of lobe/channel complexes including one or more lobes), at the lobe/channel complex set level (which comprises a plurality of lobe/channel complex sets, each of the plurality of lobe/channel complex sets including one or more lobe/channel complexes), and at the zone level (with a respective zone, such as a reservoir zone, divided into independent sub-zones, with each sub-zone having one or more lobe/channel complex sets). Thus, one hierarchy comprises the lobe/channel level, the lobe/channel complex level, the lobe/channel complex set level, and the zone level. In this regard, the hierarchy may include a lower level (such as the lobe/channel level, which comprises the lowest level or most elemental level), one or more intermediate levels (such as the lobe/channel complex level and the lobe/channel complex set level), and a higher level (such as the zone level comprising the highest level). In particular, the hierarchy may include at least two levels, at least three levels, at least four levels, at least five levels, or greater than five levels.

In one or more embodiments, the hierarchical conditioning methodology may: (i) select template(s) according to one of the levels in order to generate template instances; and (ii) iteratively condition the template instances at the different levels based on data tailored to the respective level. With regard to (i), the template may be selected from currently available templates and/or from machine-learned templates (with the machine-learned templates discussed in further detail below). For example, one or more lobe/channel complex templates may be selected for lobe/channel complex template instances. In one or some embodiments, a single lobe/channel complex template is available for selection. In this regard, multiple lobe/channel template instances are selected to fill a respective sub-zone. Alternatively, multiple templates are available to select from, such as one or more lobe templates (e.g., a single lobe template, or multiple lobe templates (such as lobe template #1, lobe template #2, etc.) and one or more channel templates (e.g., a single channel template, or multiple channel templates (such as channel template #1, channel template #2, etc.). Thus, after instantiation, a respective sub-zone has multiple lobe/channel complex template instances. In this regard, there may typically be multiple instances of one or multiple templates associated with each sub-zone. Those template instances may be warped and then stacked on the top of each other to constitute a model for the target sub-zone, in effect mimicking the depositional process. Further, the template, such as the lobe/channel complex template, carries undefined parameters. Once the parameters are fixed/selected, the template becomes a template instance.

After instantiation of the lobe/channel complex template instances, the lobe/channel complex template instances are conditioned with data tailored to one or more of the different levels. As discussed above, well log data and/or seismic data may be available. Typically, the well log data may comprise measured data (such as from the reservoir in question) or simulated data, and may describe the fine scale (e.g., on the order of data at ⅓ foot intervals). Likewise, the seismic data may comprise measured data (such as from the reservoir in question) or simulated data, and may describe the fine scale (e.g., at the 1 meter level). Further, the well log data may be limited in its scope, such as in discrete vertical sections of the reservoir. In order to condition the lobe/channel complex template instances, the data, such as the well log and/or the seismic data, may be analyzed or modified to different respective scales or levels.

Further, the conditioning may be directed to one or more aspects of the template instances. The one or more aspects of the template instances may comprise, but are not limited to, one or both of: configuration geometry (e.g., dimensions of lobe/channel; dimensions of lobe/channel complex; dimensions of lobe/channel complex set); location and direction, or properties (e.g., any one, any combination, or all of: porosity; grain size; facies; amount of shale; amount of sand; etc.). As discussed further below, conditioning may modify the configuration geometry and/or the properties associated with the template instances.

Further, in one or some embodiments, the conditioning of the template instances may be performed iteratively, such as by using data at at-least two different scales. As one example, conditioning may be performed iteratively using data at a larger scale (such as at the larger scale using larger-scale data or at the medium scale using medium-scale data) and at a smaller scale (such as at the fine scale using fine-scale data). As another example, conditioning may be performed iteratively using data at least three different scales, such as conditioning using data indicative of large-scale features (e.g., conditioning using the large-scale features to modify one, some, or all of the configuration geometry, location, or the properties), conditioning using data indicative of medium scale features (e.g., conditioning using the medium-scale features to modify one, some or all of the configuration geometry, location, or the properties), and conditioning using data indicative of fine-scale features (e.g., conditioning using the fine-scale features to modify one, some or all of the configuration geometry, location, or the properties). Further, various sequences of iterative conditioning using data for the different scales is contemplated. As one example, the iterative conditioning may comprise conditioning using the data indicative of large-scale features, thereafter conditioning using the data indicative of medium-scale features, and thereafter conditioning using the data indicative of fine-scale features. In addition, various types of conditioning are contemplated. As merely one example, a Bayesian conditioning framework may be used.

As discussed above, various data, such as well log and/or seismic data, may be available. The data may be modified to extract data for the different scale features, such as data indicative of any one, any combination, or all of levels above the elemental level (e.g., for a three-level hierarchy, indicative of large-scale features and/or data indicative of medium scale features). For example, when conditioning at the lobe/channel complex set level, the data may be up-scaled to highlight large-scale features so that the conditioning at the lobe/channel complex set level more closely matches the highlighted large-scale features. In particular, features at the lobe/channel complex set level, such as trends, averages, or the like, may be gleaned from the data (such as the well log and/or seismic data) that is at the fine-scale level. Various trends (such as trend constraints) at the lobe/channel complex level are contemplated. As one example, net versus non-net trends, as gleaned from the fine-scale level data, may be used to condition at the lobe/channel complex set level. Other examples, without limitation, include spatial trends, such as decreasing or increasing porosity and/or permeability across the reservoir, decreasing or increasing shale versus sand in different regions (e.g., more sand at lower depths versus more shale at higher depths; more sand in a center of a lobe versus greater shale farther from the center of the lobe), more sand in one direction versus another direction (e.g., more sand in the east than in the west), or more sand within a specified region than outside said region. In this regard, the lobe/channel complex template instances may be conditioned at the lobe/channel complex set level using data tailored to that respective level, such as: (i) upscaled data, which may be derived from fine-scaled data (e.g., measured seismic data and/or well log data) in the respective reservoir and configured to identify larger-scale spatial features and/or larger-scale trends of one or more properties in the respective reservoir; and/or (ii) simulated large-scale feature data (e.g., simulated well log and or simulated seismic data that is upscaled in order to highlight large-scale features). In this regard, conditioning using the data highlighting large-scale features may modify the configuration (such as configuration geometry) and/or properties aspects of the template instances.

As another example, when conditioning at the lobe/channel complex level, the data may be gleaned to model medium-scale features. The data may comprise any type of fine-scale feature data described herein, including actual and simulated fine-scale feature data. In particular, features at the lobe/channel complex level, such as to honor EoD (Environment of Deposition) constraints (e.g., lobe, channel, or mud) or sub-EoD constraints (e.g., proximal lobe, medial lobe, distal lobe, or ultradistal lobe), may be used to condition the template instances. Similarly, the lobe/channel complex template instances may be conditioned at the lobe/channel complex level using the identified medium-scale spatial features and/or medium-scale trends of one or more properties in order to modify configuration and/or properties aspects of the template instances. As still another example, when conditioning at the lobe/channel level, the data, such as the seismic data, may be used to model fine-scale features (such as fine-scale property distributions). Again, the lobe/channel complex template instances may be conditioned at the lobe/channel level using the identified small-scale spatial features and/or small-scale trends of one or more properties in order to modify configuration and/or properties aspects of the template instances. In this way, the iterative conditioning may use data tailored to the different levels in order to iteratively modify the model.

For illustration purposes, the discussion below discusses a deep-water channel-lobe environment. The disclosed hierarchical conditioning may be applied to other EoDs as well. In that regard, any discussion regarding deep-water channel-lobe environment may be applied to other depositional environments as well.

As discussed above, a machine learning or functional form template may be used in order to generate the geological or the reservoir model. In one implementation, the template instance may be 2-D (e.g., a pixel image) or 3-D (e.g., a voxel, which comprises a 3D pixel where the dimensions are specific to the seismic geometry and may be measured as an inline X crossline×Z sample). Alternatively, in one or some embodiments, the template instance may have greater than 3 dimensions, such as at least 4 dimensions, at least 5 dimensions, at least 6 dimensions, at least 7 dimensions, at least 8 dimensions, or more. For example, a three-dimensional voxelization with eight properties attached to each voxel might result in eleven dimensions. As discussed above, various properties may be considered, such as grain size distribution, shale distribution, sand distribution, porosity distribution, or the like. The various properties, such as trends associated with the various properties, may be used so that the template comprises a high-dimensional tensor/matrix of data.

Further, as discussed above, the template may be directed to one or more levels, such as any one, any combination, or all of: at the large-scale level; at the medium-scale level; and at the small-scale level. Thus, in one or some embodiments, the template may comprise an intermediate level template, comprising a lobe/channel complex template, which may be used as a building block for the geological model. The template, such as the lobe/channel complex template and/or the lobe/channel complex set template, may be generated for use with the methodology described above.

Alternatively, the template may be multi-dimensional based on the different levels, including one or more various properties at large-scale level, one or more various properties at the medium-scale level, and one or more various properties at small-scale level. The segmentation of the template into the different levels may assist in analysis, such as within a respective level, or with regard to identifying trends that cross different levels. As discussed above, due to the fractal nature (e.g., self-similar nature) of the subsurface, there may be consistent patterns at the different levels, such as at the lobe/channel level, the lobe/channel complex level, and the lobe/channel complex set level. The analysis of the data at the different levels may either amplify the differences between the data at the different levels or suppress the differences. In particular, analyzing the data at the different levels may exploit the fractal nature of the subsurface, thereby potentially removing noise consistent across the different levels and potentially amplifying trends that are present in the data at the different levels.

Geological features may be defined or described in one of several ways. As one example, a thickness field may be representative of geological features. Traditionally, the thickness field may be discretized by pixels akin to an image, where each pixel has an associated value (or two values). In contrast, reservoir modeling may seek to model the thickness field, with each thickness field having a number of associated values (e.g., a multi-dimensional tensor). In one specific example, the thickness field may be based on multiple levels or layers, such as a lobe/channel layer with associated properties (e.g., a lobe/channel layer dimension including properties associated with a lobe/channel layer), a lobe/channel complex layer with associated properties (e.g., a lobe/channel layer complex dimension including properties associated with a lobe/channel complex layer), a lobe channel complex set layer with associated properties (e.g., a lobe/channel layer complex set dimension including properties associated with a lobe/channel complex set layer). Because of the hierarchical/fractal nature of the subsurface, the analysis of the multi-dimensional tensor based on the thickness field across the different layers may assist in conditioning in order to define the geometry in one or more geological objects in a respective layer or across layers.

The functional form modeling (FFM) may thus mimic the geological depositional and erosional processes which form the geological features. Specifically, the parameter sets for the different elements of the lobe/channel complex template may be correlated and subject to a set of constraints (e.g., geological feasibility). In particular, the subsurface comprises lobe/channels, with multiple lobe/channels forming a lobe/channel complex, and multiple lobe/channel complexes forming a lobe/channel complex set, as discussed above. One manner in which to generate a template for the subsurface is to specify the parameters for each of the individual lobes, thereby basing the template on the set of parameters at the lobe level. Alternatively, the template may be directed to the lobe/channel complex level. In one or some embodiments, the template may be parameterized at the lobe/channel complex level (such as via functional form modeling). Specifically, instead of parameters at the lobe/channel level, the parameters are directed to the lobe/channel complex, which is the aggregation of the lobes/channels. The parameters at the lobe/channel level may thus represent a subset of the entire set of parameters (e.g., a latent space of the parameter set) and indicative of the geological feasible set of parameters. Thus, the latent space, which represents the parameter space of these large scale features, may be explored within a conditioning approach in order to build and condition a geological model. The template may be generated in one of several ways. In one or some embodiments, the template may be generated using supervised or unsupervised learning on a set of functional form parameters to extract the latent space.

Alternatively, the template directed to the lobe/channel complex level may be built using a generative model, as discussed further below. Specifically, deep learning networks are utilized to parameterize the template, such as for the large scale features at the level of lobe/channel complexes.

Further, various types of templates may be generated including any one, any combination, or all of: (1) a generic template (which may be used with different types of reservoirs); (2) template tailored to a type of reservoir (e.g., depending on type of channel/lobe, such as tide-dominated, wave-dominated, or fluvial-dominated; shoreface or shazams that transition different types into each other); or (3) templated tailored to a specific reservoir. With regard to (3), due to advancements in learning methods (such as disclosed below) and/or increased computational capacity, templates may be tailored to the specific reservoir prior to conditioning. For example, a particular deposition of environment, which created the specific reservoir, may be used in the template building.

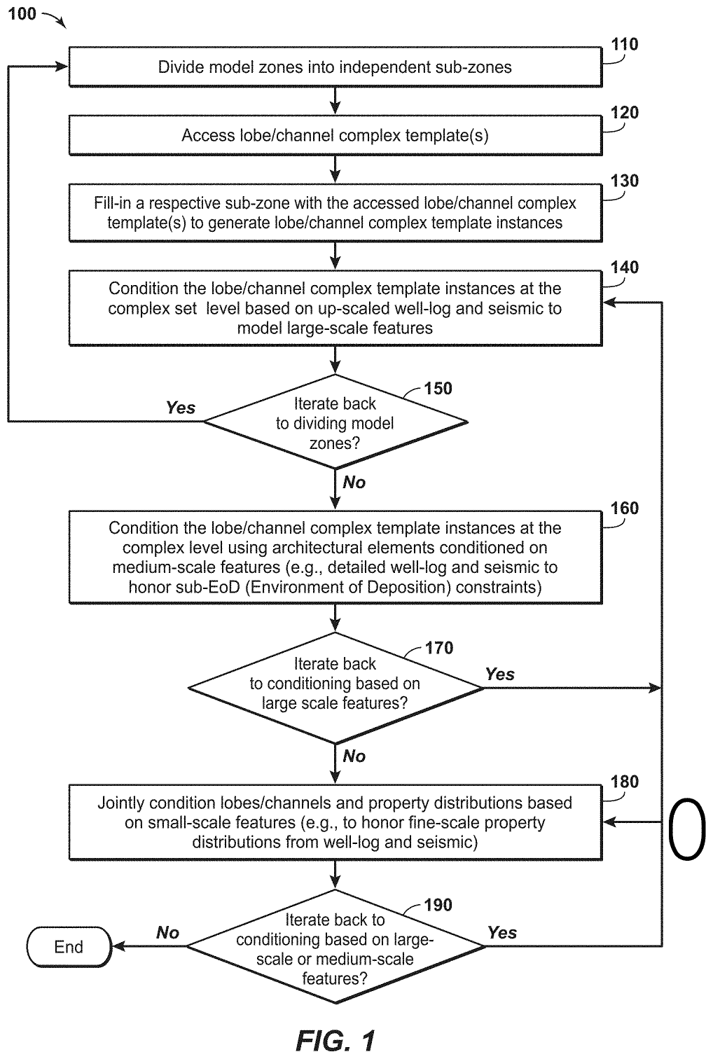

Referring to the figures, FIG. 1 is a flow diagram 100 of an example hierarchical conditioning methodology for building and conditioning a geological model. As discussed above, the geological model, such as the reservoir model, may be generated in one of several ways including building the model, not from initially conditioning using fine-scale data, but using multiple complex set template instances to fill a defined volume. In one or some embodiments, the defined volume may comprise a subzone. In this regard, at 110, the model zones may be divided, such as into independent sub-zones or a hierarchy thereof. In one or some embodiments, the model zones are divided into the independent sub-zones based on regional correlation of non-net (e.g., the portion of the subsurface not ascribed as part of the reservoir) by interpretation or automated workflow (e.g., scenario generation, seismic guided). Thus, division of the model zones may be performed in one of several ways and may indicate the different layers in the subsurface. In particular, various data, such as seismic data, may be analyzed in order to identify various formations, faults, or the like in the subsurface, with the identified formations, faults, etc. being used to divide the model zones into the independent sub-zones. In this way, the division may mirror the geological formations in the subsurface. Merely by way of example, a subsurface may be segmented or divided into a plurality of sub-zones, such as for a volume with a 100 meter depth being divided, based on the data, into a top 40 meter volume, a middle 20 meter volume and a bottom 40 meter volume. Within the present disclosure, a subzone is a zone or a subdivision thereof that may be modelled or filled with templates independently of other subzones.

As discussed above, the geological model may be instanced using multiple lobe/channel complex templates, and iteratively conditioned using different scaled data. To that end, at 120, one or more lobe/channel complex templates may be accessed. As discussed above, multiple lobe/channel complex template instances are assigned to a respective sub-zone. The multiple lobe/channel complex template instances may be based on a single lobe/channel complex template or multiple lobe/channel complex templates. For example, a plurality of lobe/channel complex templates may be available. A subset of the plurality of lobe/channel complex templates available may be selected or accessed based on the specific reservoir subject to modeling (e.g., whether the accessed template(s) are appropriate for modeling the specific reservoir). In one or some embodiments, in one embodiment, a single lobe/channel complex template may be used for the multiple lobe/channel complex template instances. In another embodiment, a single lobe complex template and a single channel complex template may be used for the multiple lobe/channel complex template instances. In still another embodiment, multiple lobe complex templates (e.g., lobe complex template #1, lobe complex template #2, etc.) and multiple channel complex templates (e.g., channel complex template #1, channel complex template #2, etc.) may be used.

At 130, a respective sub-zone is filled with the accessed lobe/channel complex template(s) in order to generate lobe/channel complex template instances. Thus, the different sub-zones may be filled with multiple lobe/channel complex template instances. In one or some embodiments, the same lobe/channel complex templates is used for the multiple lobe/channel complex template instances. Alternatively, the different sub-zones may use different lobe/channel complex templates for the multiple lobe/channel complex template instances (e.g., first sub-zone uses lobe/channel complex template #1 and lobe/channel complex template #2, second sub-zone uses lobe/channel complex template #3 only, and third sub-zone uses lobe/channel complex templates #1 and lobe/channel complex #3).

Further, the multiple lobe/channel complex template instances for a respective zone, which may be stacked, may be conditioned. As discussed above, conditioning may be iterative based on differently scaled data. For example, at 140, the lobe/channel complex template instances are conditioned (e.g., based on volume) at the complex set level based on up-scaled well log and seismic to model large-scale features. In particular, up-scaled data, as derived from the well log and/or seismic data and indicative of large-scale features, may be used to condition the multiple lobe/channel complex template instances. Conditioning may modify the multiple lobe/channel complex template instances in one or multiple of the configurational geometry (e.g., the contour of the lobe/channel complex instance and/or an interior of the lobe channel complex instance), location or directions, and properties associated with the template instances. As discussed above, the conditioning of the configuration, geometry, and the properties may be performed serially or in combination. In practice, the multiple lobe/channel complex instances, stacked together, are conditioned in combination.

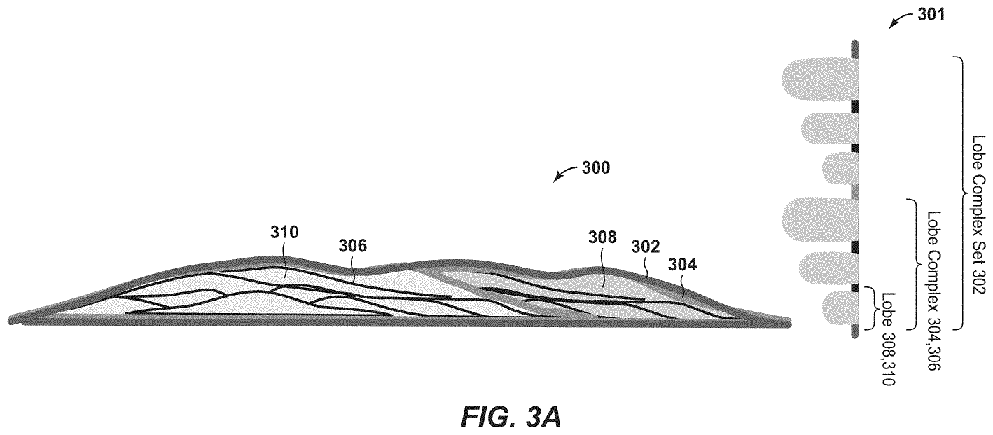

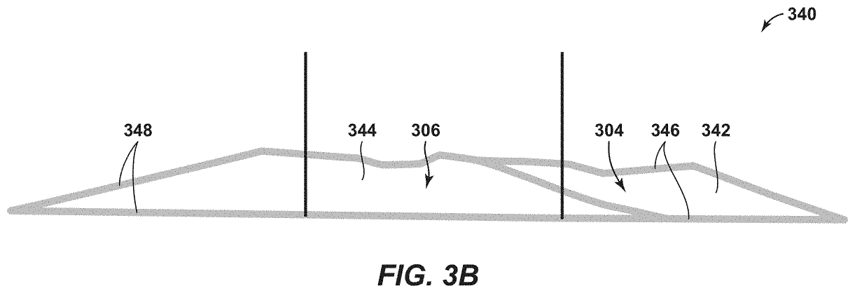

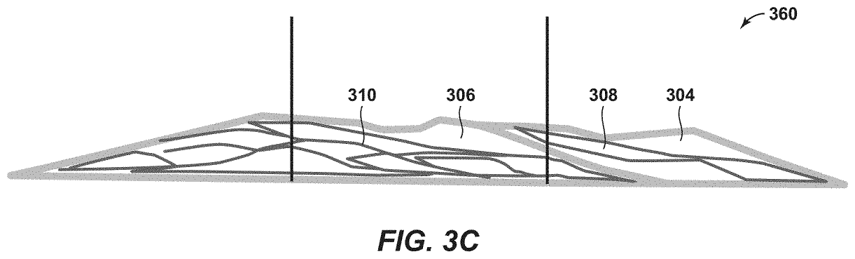

For example, division of a model zone may result in at least two independent sub-zones 342, 344 as illustrated in the cross-section depiction 340 of FIG. 3B. As shown, the two independent sub-zones 342, 344 have a unique shape. A first set of multiple lobe/channel complex template instances may be assigned to independent sub-zone 342 and a second set of lobe/channel complex template instances may be assigned to independent sub-zone 344. As discussed above, in one embodiment, the first set of multiple lobe/channel complex template instances and the second set of multiple lobe/channel complex template instances are derived from the same template. Alternatively, the first set of multiple lobe/channel complex template instances and the second set of multiple lobe/channel complex template instances are derived from different templates.

In turn, the first lobe/channel complex template may be conditioned configurationally such that both an exterior contour of the first set of multiple lobe/channel complex template instances fits or matches the contour of independent sub-zone 342 and an interior of the first set of multiple lobe/channel complex template instances is deformed as well, resulting in a contour 346 of the first set of multiple lobe/channel complex template instances matching the contour of independent sub-zone 342. Likewise, the second set of multiple lobe/channel complex template instances may be conditioned such that both an exterior contour of the second set of multiple lobe/channel complex template instances fits or matches the contour of independent sub-zone 344 and an interior of the second set of multiple lobe/channel complex template instances is deformed as well, resulting in a contour 348 of the second lobe/channel complex template matching the contour of independent sub-zone 344.

Further, as discussed above, the data selected for performing the conditioning at 140 of the lobe/channel complex template to a respective sub-zone may be selected as probative or representative of the larger-scale, such as at the lobe/channel complex set level. For example, data, such as seismic data, well logs, or the like may be analyzed in order to derive the up-scale data. In particular, the data may be subject to filtering, such as low-pass filtering, in order to obtain the lower frequency information indicative of the larger-scale features.

At 150, it is determined whether to iterate back to 110 to dividing the model zones. For example, there may be multiple potential options in which to divide the model zones. Based on the data available, a best option, selected from the multiple options, may be selected. In the event that the conditioning at 140 does not result in a geologically feasible model, the flow diagram 100 may iterate back to 110 in order to select another of the multiple potential options of dividing the model zones. In particular, a potential option at a larger hierarchical scale may initially be selected. In the event that there is no convergence or compatibility for the potential option selected at the larger scale with any feasible option at the finer hierarchical scale, the flow diagram 100 may iterate backward.

After conditioning at the lobe/channel complex set level, additional conditioning may be performed using smaller-scaled data. Specifically, the multiple lobe/channel complex template instances, already conditioned based on the large-scale data, are subject to further conditioning, such as using data probative at the lobe/channel complex level. In particular, at 160, lobe/channel complex template instances are constructed using architectural elements conditioned on medium-scale features (e.g., detailed well log and seismic to honor sub-EoD constraints). Again, the conditioning at 160 may modify the configuration geometry and the properties at the lobe/channel complex level for the multiple lobe/channel complex template instances. In this regard, data, such as seismic data, well logs, or the like may be analyzed in order to obtain higher frequency data which is indicative of the lobes/channels within a respective sub-zone.

At 170, it is determined whether to iterate back to 140 to conditioning using at the lobe/channel complex set level using the large-scale features. For example, there may be multiple potential options in which to condition the lobe/channel complex template instances at the lobe/channel complex set level. Based on the data available, a best option, selected from the multiple options, may be selected. In the event that the conditioning at 160 does not result in a geologically feasible model, the flow diagram 100 may iterate back to 140 in order to select another of the multiple potential options of conditioning at the lobe/channel complex set level.

If iteration back to 140 is not warranted, further conditioning may be performed, such as at a still smaller scale. In particular, at 180, the system jointly conditions lobes/channels and property distributions based on small-scale features (e.g., to honor fine-scale property distributions from well log and seismic). In this way, step 180 may be used to fine tune the properties of the lobe/channel complex template instances to comport with the available data.

At 190, it is determined whether to iterate back to conditioning based on large-scale or medium-scale features. For example, the lobe/channel complex template instances, after conditioning based on the small-scale features, may be analyzed to determine whether to further condition based on the large-scale features or medium scale features. If so, flow diagram 100 may iterate back to 140 or 160, respectively. If not, flow diagram ends.

Thus, FIG. 1 illustrates one sequence of conditioning (e.g., conditioning at the complex set level, at the complex level, at the lobe/channel level). FIG. 1 is merely for illustration purposes. In particular, one, some, or all of the conditioning blocks illustrated in FIG. 1 may be repeated, reordered, or replaced with other types of conditioning. As one example, the sequence of conditioning may be different from that illustrated in FIG. 1. As another example, conditioning at a different level may be used in addition to, or instead of, the conditioning illustrated in FIG. 1.

Further, in one or some embodiments, the flow diagram 100 illustrated in FIG. 1 may be automated and operate without user input. Alternatively, the system may be configured to flexibly receive user input at one or more stages in order to modify operation of the flow diagram 100. As one example, after conditioning at any level, such as at the complex set level, the complex level, or the elemental level, a user may examine and modify the output generated after conditioning at the respective level for geological feasibility. As another example in which multiple geological models are built, user input may rank and/or discard one or more of the multiple geological models based on geographical feasibility.

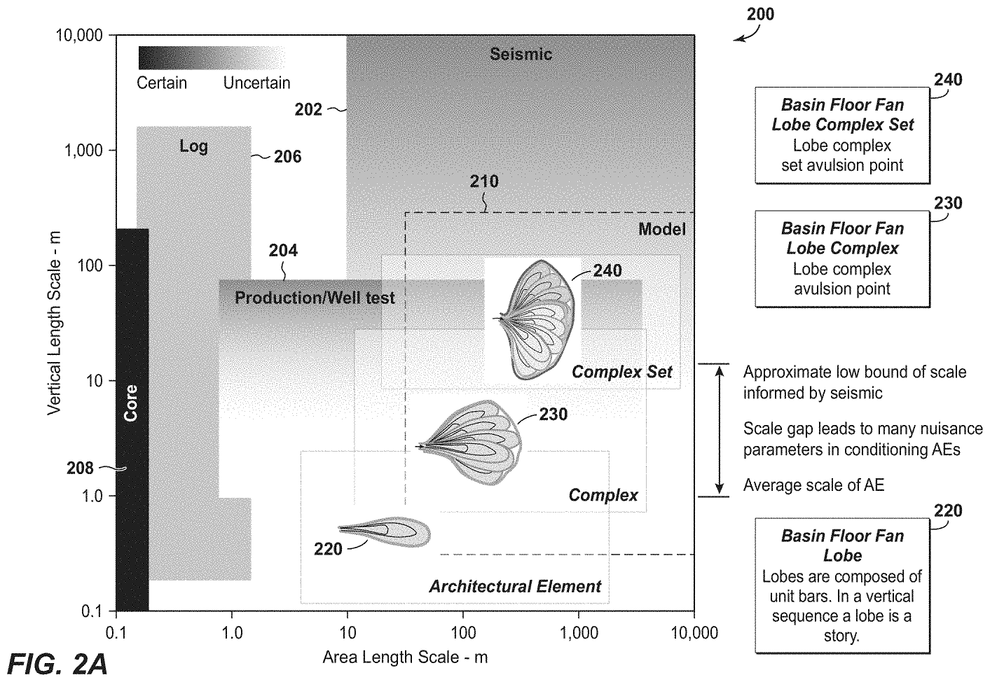

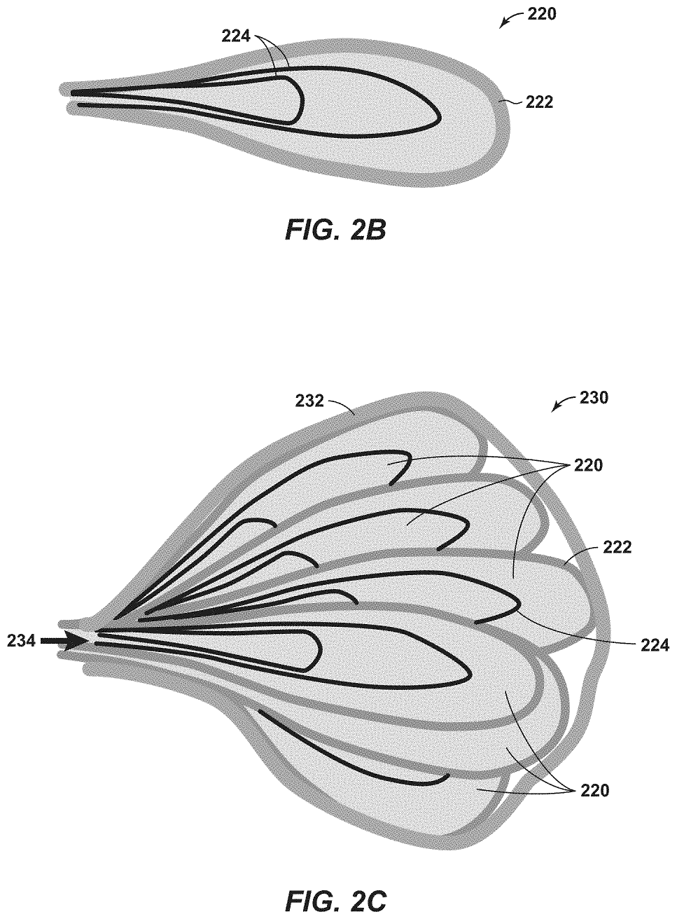

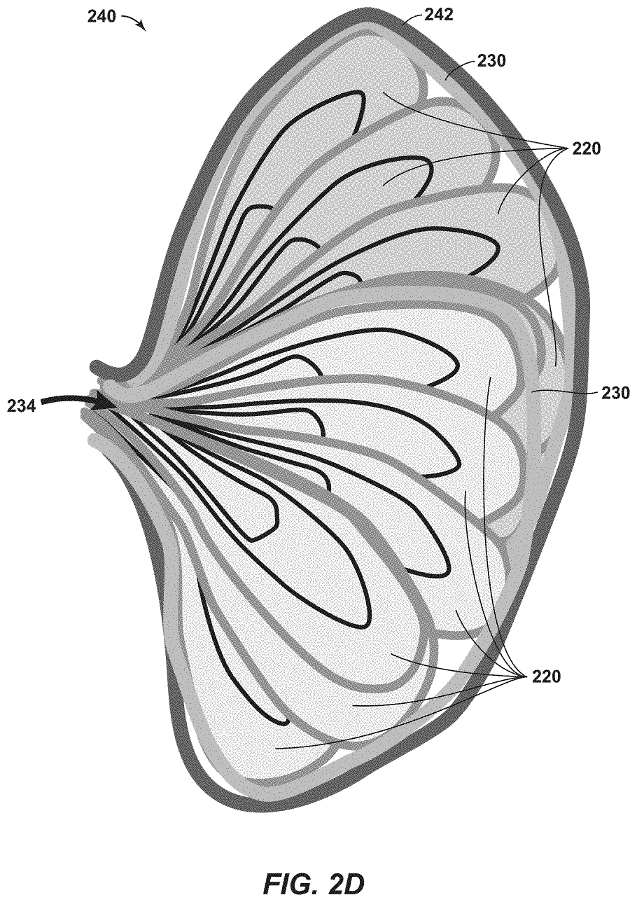

FIG. 2A is a depiction 200 of the resolution of information from core, log, seismic and production data compared to the resolution of model building blocks in which the horizontal and vertical axes represent both the spatial and vertical scale and spatial coverages. Specifically, FIG. 2A illustrates different levels, such as the architectural element level (such as the lobe/channel level that includes lower hierarchy level structures, such as lobe/channel 220), the lobe/channel complex level (that includes a lobe/channel complex 230), and the lobe/channel complex set level (that includes a lobe/channel complex set 240). Further, FIG. 2A illustrates different sources of data, such as seismic data 202, production/well test data 204, log data 206, and core data 208. FIG. 2A further illustrates the space for the model 210. FIG. 2A demonstrates that the model contains a resolution or coverage gap for which no observational data are available (e.g., core, log, production data, well tests, or seismic). Instead geologic concepts are used to fill this gap. But these concepts exist at multiple hierarchical levels (architectural element, complex, complex set, etc.) exemplifying the need for hierarchical model-building and conditioning by bridging between the smallest conceptual element to the observational data.

FIGS. 2B-D include depictions of the lobe/channel 220, the lobe/channel complex 230, and the lobe/channel complex set 240. As discussed above, multiple lobe/channel complex template instances may be used. In particular, FIG. 2B illustrates a lobe/channel 220, including a lobe 222 and one or more channels 224. In this regard, FIG. 2B is an example of a lobe/channel template, which may be part of a lobe/channel complex template with various parameters defined, such as various defined configurations (e.g., width and length of lobes) and geological properties. FIG. 2C illustrates a lobe/channel complex 230, which includes an exterior contour 232, a plurality of lobe/channels 220, and a lobe/channel complex avulsion point 234. In this regard, FIG. 2C may be an illustration of a lobe/channel complex template instance. Alternatively, the lobe/channel complex template instance may be defined by a series of equations. An example of the series of equations is disclosed in Xiuli Gai, Xiao-Hui Wu, Bogdan Varban, Kathryn Sementelli, Gregory Robertson, “Concept-Based Geologic Modeling Using Function Form Representation”, Society of Petroleum Engineers, SPE-161795-MS, pg. 2678-2690, Abu Dhabi International Petroleum Conference and Exhibition (2012), incorporated by reference herein in its entirety. These equations allow formation of surfaces, thicknesses, trends, local coordinates, or properties that can be used to build a numerical representation of the subsurface, i.e., a geologic or reservoir model. FIG. 2D illustrates a lobe/channel complex set 240, which includes an exterior contour 242, one or more lobe/channel complexes 230 (FIG. 2D illustrates 2 lobe/channel complexes 230, although fewer or greater numbers of lobe/channel complexes 230 are contemplated), lobe/channels 220 within the lobe/channel complexes 230, and a lobe/channel complex set avulsion point 244. As shown in FIGS. 2B-D, various parts of the lobes/channels 220, the lobe/channel complexes 230 and the lobe/channel complex sets 240 may be deformed, such as via conditioning as discussed above, and further below with regard to FIGS. 3A-C. In particular, parts of the multiple lobe/channel complex template instances (such as the contour and/or the interior) may be deformed based on conditioning.

FIG. 2A illustrates the challenge in building and conditioning realistic models using functional forms. As shown in FIG. 2A, the data required for proper conditioning of models at the level of architectural elements (e.g., lobe/channel geological features) are unavailable. In particular, the lobe/channel complex set level is approximately the low bound of the scale that is informed by the seismic data, whereas the lobe/channel complex level is the average scale of the architectural elements (AEs). In this way, there is a scale gap that leads to many nuisance parameters in conditioning the architectural elements, with the lobe/channel complex sets potentially being too complicated to parameterize. To remedy this, the hierarchical conditioning methodology, such as described in FIG. 1, may be used. In particular, the hierarchical conditioning methodology may use multiple large-scale template instances, such as at the level of lobe/channel complexes as the building blocks of the geological model for inversion, since data are most informative at this level, as discussed above. The construction and conditioning of the large-scale template may be performed using machine learning approaches, as discussed in more detail below.

FIG. 3A is a cross-section depiction 300 of the lobes 308, 310, lobe complexes 304, 306, and lobe complex set 302 of a reservoir, and a graphic 301 showing the relationships between the lobes 308, 310, lobe complexes 304, 306, and lobe complex set 302. As illustrated above with regard to FIGS. 2A-D, there is a hierarchy with regard to the lobes 308, 310, lobe complexes 304, 306, and lobe complex sets 302. Further, FIG. 3A illustrates the result after performing at least part of the flow diagram in FIG. 1 (such as at least through 160), in which the shapes of the lobes 308, 310, lobe complexes 304, 306, and lobe complex set 302 are deformed (the property distributions assigned at 180 are not illustrated in FIG. 3A).

FIG. 3B is a cross-section depiction 340 of reservoir model zone divided into independent sub-zones 342, 344 with the contour of the lobe/channel complex templates being deformed based on the data. In particular, a contour 346 of a first lobe complex 304 may be deformed in order to fit within sub-zone 342, and a contour 348 of a second lobe complex 306 may be deformed in order to fit within sub-zone 344. Further, an interior of the first lobe complex 304 may subsequently be deformed (such as by deforming one or more lobes/channels within the first lobe complex 304), and an interior of the second lobe complex 306 may subsequently be deformed (such as by deforming one or more lobes/channels within the second lobe complex 306). This deformation of the lobes/channels is illustrated in the cross-section depiction 360 of FIG. 3C.

Thus, an intermediate construct, in the form of the lobe/channel complex template, may be used in order to instantiate the model to conform to different hierarchy levels. In particular, the lobe/channel complex set may be instantiated using multiple lobe/channel complex templates, and thereafter the multiple lobe/channel complex template instantiation may be conditioned to conform to the available data.

As discussed above, a template, such as a lobe/channel complex template, may be used. Various methodologies may be used in order to generate a geologically feasible lobe/channel complex template. A general lobe/channel complex template may be composed of individual lobe/channels and may include a set of corresponding parameters, which their assignment may result in both feasible and unfeasible complex. Parameterizing the complex template may be accomplished in at least the following ways: (1) identifying the subspace of individual lobe/channel parameters by using the machine learning to encode the parameters that are directed to the feasible template; or (2) using machine learning to create generative tools capable of constructing feasible complex templates. The feasible template may take one of several forms. In one or some embodiments, the subspace of parameters may be identified that when used in a set of lobe templates create a feasible lobe complex. Alternatively, the subspace of lobe-complex models may be identified in order to create a lobe-complex template that may be expressed in a different mathematical form than the lobe template.

Specifically, functional form modeling may be used to mimic the geological depositional and erosional processes which form the geological features, as discussed above. In particular, the functional form model comprises a mathematical model involving an explicit set of equations that describe the relationships among the variables contained in the model. Thus, the functional form model may include variables, and equations for the variables that are based on known geological constructs.

For purposes of explanation, consider Fₜ(uₜ) as representing the forward model which generates a large-scale feature and is a function of uₜ. In this example of functional form modeling, Fₜ is designated as the functional form model and uₜ is designated as the set of parameters corresponding to the individual elements (e.g., the lobes) which construct the large-scale feature (e.g., the lobe complex). The parameterization of the large scale features may be accomplished in one of several ways.

In one way, uₜ may be parameterized in terms of a latent space, which produces geologically feasible/acceptable models at the lobe/channel complex level. For example, a function ε(ũₜ) may be generated to indicate the subspace of parameters that are geologically feasible. In particular, ε(ũₜ) may comprise ε(ũₜ)≈uₜ such that Fₜ≈Fₜ(ε(ũₜ)), with Fₜ is feasible lobe/channel complex.

In effect, ε may be used to generate the lobe/channel complex template. For example, the lobe/channel complex template may be composed of multiple lobes/channels, each of which having a corresponding set of parameters. By using ε, the multiple sets of parameters for the lobes/channels may be encoded into a smaller set of parameters that generates a geologically feasible lobe/channel complex template.

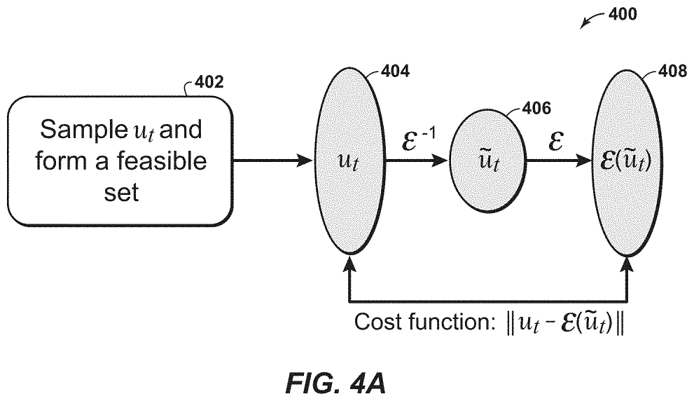

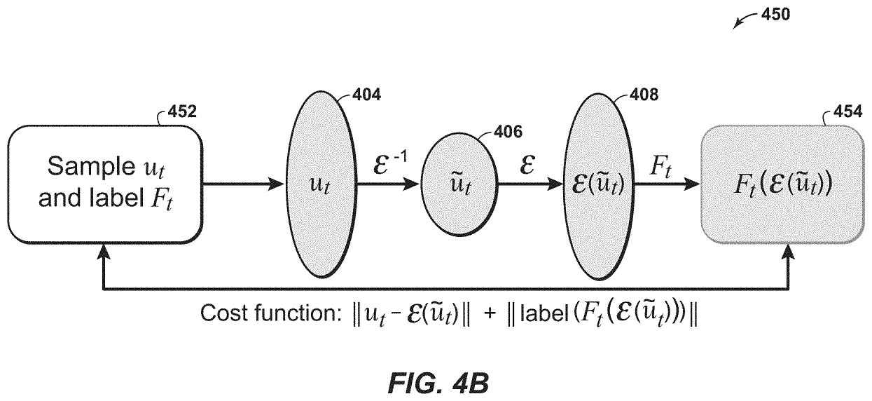

FIGS. 4A-B shows two instances of using unsupervised learning (FIG. 4A) and supervised learning (FIG. 4B) for training an auto-encoder in order to obtain ε. In particular, an autoencoder, or other type of artificial neural network, may be used to learn efficient data codings in an unsupervised manner, with the aim of learning a representation (such as an encoding) for the set of data. In contrast, supervised learning is the machine learning task of learning a function that maps an input to an output based on example input-output pairs.

FIG. 4A is a block diagram 400 of lobe/channel complex template parametrization of large-scale features. uₜ 404 (the set of parameters) is sampled in order to form a feasible set of parameters (which is a subset of the entire set of parameters for uₜ). In turn, uₜ 404, using ε⁻¹, may generate ũₜ 406, which using ε generates ε(ũₜ) 408, with a loss function, such as, for example, the loss function ∥uₜ−ε(ũₜ)∥, used as input to both uₜ 404 and ε(ũₜ) 408.

FIG. 4B is a block diagram 450 of lobe/channel complex template parametrization of large-scale features using an auto-encoder with supervised learning. At 452, the uₜ is sampled and Fₜ, the feasible lobe/channel complex, is labeled. Ultimately, Fₜ(ε(ũₜ)) 454 is generated where the system learns ε(ũₜ)≈uₜ such that Fₜ≈Fₜ(ε(ũₜ)). As merely one example, loss function ∥uₜ−ε(ũₜ)∥+∥label(Fₜ (ε(ũₜ))) may be used as input to both uₜ 404 and Fₜ (ε(ũₜ)) 454.

Alternatively, the lobe/channel complex template may be generated using machine learning, such as statistical generative modeling, as discussed above. Statistical generative modeling may implicitly or explicitly model the target distribution. The target distribution on the feasible space of the large-scale features is given by an ensemble of examples, generated by FFM or process-based simulations (James K. Miller, Tao Sun, Hong-Mei Li, Jonathon Stewart, Coralie Genty, Dachang Li, Colin Lyttle, “Direct Modeling of Reservoirs through Forward Process-based Models: Can We Get There?”, International Petroleum Technology Conference, IPTC 2008, DO 10.2523/12729-MS (2008)). This approach may be challenging in at least two respects: (1) the exact form of such generative model is unknown given the complex geometry and property distribution of large-scale features; and (2) an effective metric to quantify the distance of two distributions is may be difficult to define.

Regardless, a statistical generative model (e.g., template parameterization \tilde{F}ₜ(\tilde{ũ}ₜ)) may be constructed such that the induced distribution approximates the statistical distribution given by the ensemble of examples. In particular, instead of using functional forms, generative adversarial networks (GANs) may be used for template formation. In this way, a new \tilde{F}ₜ, which is a function of \tilde{ũ}ₜ, called \tilde{F}(uₜ) is generated. In this way, \tilde{F}(\tilde{ũ}ₜ) is a network which has its own parameters \tilde{ũ}ₜ, that generates the feasible lobe/channel complex template.

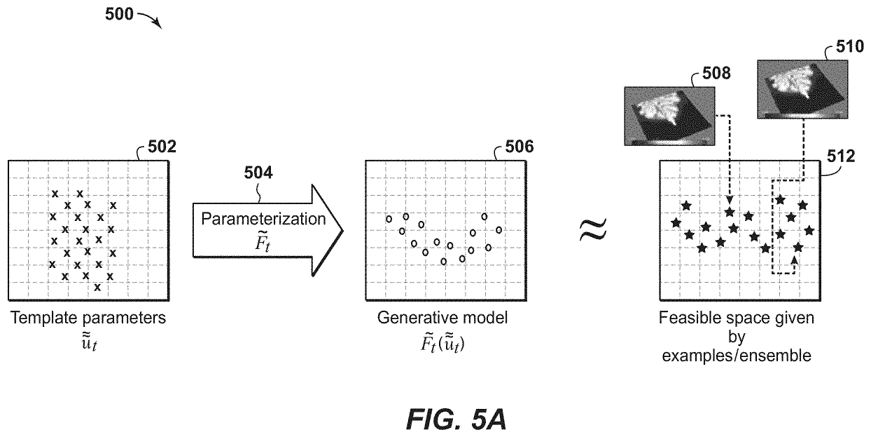

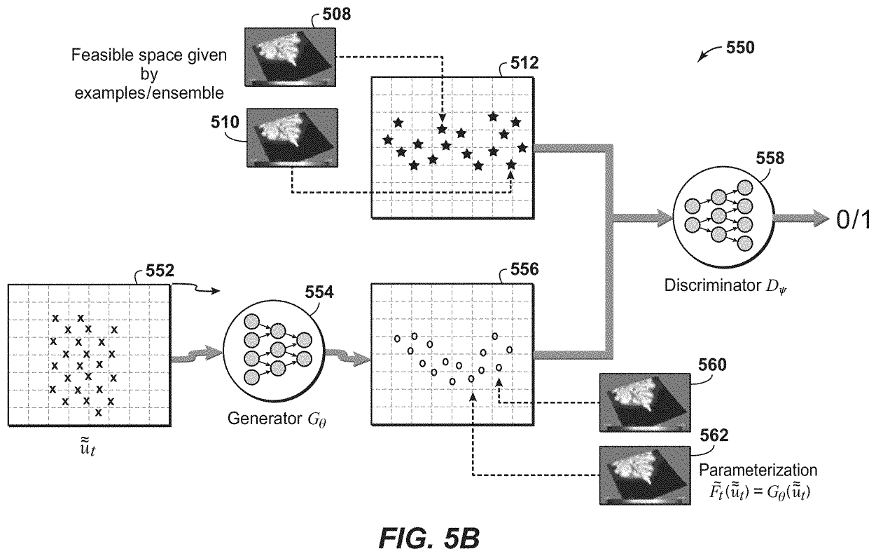

This is further illustrated in FIG. 5B, which is a block diagram of lobe/channel complex template parametrization by generative adversarial networks (GANs). Specifically, from a given distribution of template parameters \tilde{ũ}ₜ 552, commonly independently distributed, the generator network G_{θ} 554, induces a distribution 556 on the space of all generated template realizations, including the parameterization \tilde{F}ₜ(\tilde{ũ}ₜ)=G_{θ}(\tilde{ũ}ₜ) 560, 562. The discriminator network D_{ψ} 558 takes input from either the space of generated template realizations or the ensemble of examples, and produces a binary classification, 0/1. The GAN is trained alternatively between G_{θ} 554 and D_{ψ} 558 and, at the limit, the generator produces perfect replicas which the discriminator is not able to tell the difference and produce “unsure”, e.g., 0.5. The trained generator G_{θ} 554 constitutes a template parameterization given the architecture of specific generator and discriminator networks.

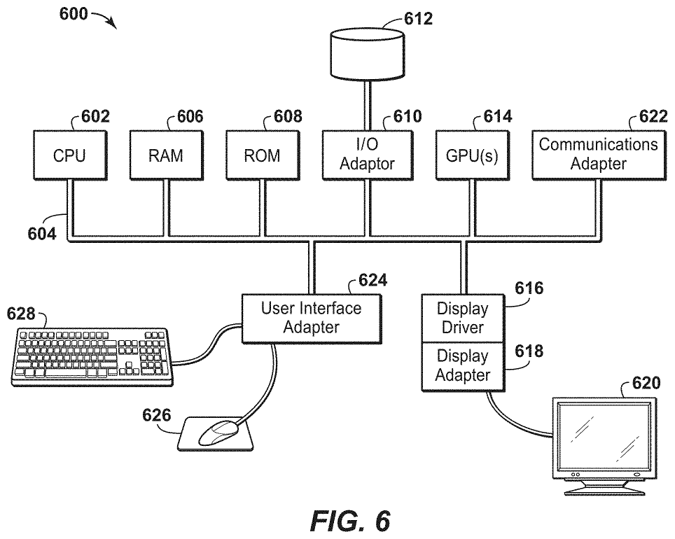

In all practical applications, the present technological advancement must be used in conjunction with a computer, programmed in accordance with the disclosures herein. For example, FIG. 6 is a diagram of an exemplary computer system 600 that may be utilized to implement methods described herein. A central processing unit (CPU) 602 is coupled to system bus 604. The CPU 602 may be any general-purpose CPU, although other types of architectures of CPU 602 (or other components of exemplary computer system 600) may be used as long as CPU 602 (and other components of computer system 600) supports the operations as described herein. Those of ordinary skill in the art will appreciate that, while only a single CPU 602 is shown in FIG. 6, additional CPUs may be present. Moreover, the computer system 600 may comprise a networked, multi-processor computer system that may include a hybrid parallel CPU/GPU system. The CPU 602 may execute the various logical instructions according to various teachings disclosed herein. For example, the CPU 602 may execute machine-level instructions for performing processing according to the operational flow described.

The computer system 600 may also include computer components such as non-transitory, computer-readable media. Examples of computer-readable media include a random access memory (RAM) 606, which may be SRAM, DRAM, SDRAM, or the like. The computer system 600 may also include additional non-transitory, computer-readable media such as a read-only memory (ROM) 608, which may be PROM, EPROM, EEPROM, or the like. RAM 606 and ROM 608 hold user and system data and programs, as is known in the art. The computer system 600 may also include an input/output (I/O) adapter 610, a graphics processing unit (GPU) 614, a communications adapter 622, a user interface adapter 624, a display driver 616, and a display adapter 618.

The I/O adapter 610 may connect additional non-transitory, computer-readable media such as storage device(s) 612, including, for example, a hard drive, a compact disc (CD) drive, a floppy disk drive, a tape drive, and the like to computer system 600. The storage device(s) may be used when RAM 606 is insufficient for the memory requirements associated with storing data for operations of the present techniques. The data storage of the computer system 600 may be used for storing information and/or other data used or generated as disclosed herein. For example, storage device(s) 612 may be used to store configuration information or additional plug-ins in accordance with the present techniques. Further, user interface adapter 624 couples user input devices, such as a keyboard 628, a pointing device 626 and/or output devices to the computer system 600. The display adapter 618 is driven by the CPU 602 to control the display on a display device 620 to, for example, present information to the user such as subsurface images generated according to methods described herein.

The architecture of computer system 600 may be varied as desired. For example, any suitable processor-based device may be used, including without limitation personal computers, laptop computers, computer workstations, and multi-processor servers. Moreover, the present technological advancement may be implemented on application specific integrated circuits (ASICs) or very large scale integrated (VLSI) circuits. In fact, persons of ordinary skill in the art may use any number of suitable hardware structures capable of executing logical operations according to the present technological advancement. The term “processing circuit” encompasses a hardware processor (such as those found in the hardware devices noted above), ASICs, and VLSI circuits. Input data to the computer system 600 may include various plug-ins and library files. Input data may additionally include configuration information.

Preferably, the computer is a high performance computer (HPC), known to those skilled in the art. Such high performance computers typically involve clusters of nodes, each node having multiple CPU's and computer memory that allow parallel computation. The models may be visualized and edited using any interactive visualization programs and associated hardware, such as monitors and projectors. The architecture of system may vary and may be composed of any number of suitable hardware structures capable of executing logical operations and displaying the output according to the present technological advancement. Those of ordinary skill in the art are aware of suitable supercomputers available from Cray or IBM or other cloud computing based vendors such as Microsoft, Amazon.

The above-described techniques, and/or systems implementing such techniques, can further include hydrocarbon management based at least in part upon the above techniques, including using the one or more generated geological models in one or more aspects of hydrocarbon management. For instance, methods according to various embodiments may include managing hydrocarbons based at least in part upon the one or more generated geological models and data representations (e.g., seismic images, feature probability maps, feature objects, etc.) constructed according to the above-described methods. In particular, such methods may include drilling a well, and/or causing a well to be drilled, based at least in part upon the one or more generated geological models and data representations discussed herein (e.g., such that the well is located based at least in part upon a location determined from the models and/or data representations, which location may optionally be informed by other inputs, data, and/or analyses, as well) and further prospecting for and/or producing hydrocarbons using the well. For example, the different stages of exploration may result in data being generated in the respective stages, which may be iteratively used by the machine learning to generate the one or more geological models discussed herein.

It is intended that the foregoing detailed description be understood as an illustration of selected forms that the invention can take and not as a definition of the invention. It is only the following claims, including all equivalents, which are intended to define the scope of the claimed invention. Further, it should be noted that any aspect of any of the preferred embodiments described herein may be used alone or in combination with one another. Finally, persons skilled in the art will readily recognize that in preferred implementation, some or all of the steps in the disclosed method are performed using a computer so that the methodology is computer implemented. In such cases, the resulting physical properties model may be downloaded or saved to computer storage.

The following example embodiments of the invention are also disclosed.

Embodiment 1: A computer-implemented method for generating one or more a geological models for a subsurface, the method comprising: for a defined volume of the subsurface: generating template instances for the defined volume; conditioning the template instances based on larger-scale data; and separately conditioning the template instances based on smaller-scale data.

Embodiment 2: The method of embodiment 1, further comprising dividing one or more geological zones into a plurality of sub-zones; and for a respective sub-zone of the plurality of sub-zones: generating the template instances for the respective sub-zone; conditioning the template instances based on the larger-scale data; and separately conditioning the template instances based on the smaller-scale data.

Embodiment 3: The method of any of embodiments 1 or 2, wherein conditioning the template instances based on the larger-scale data comprises conditioning the templates instances based on at least one of large-scale data or medium-scale data; and wherein conditioning the template instances based on the smaller-scale data comprises conditioning the template instances based on fine-scale data.

Embodiment 4: The method of any of embodiments 1-3, wherein conditioning the template instances based on larger-scale data comprises: conditioning the template instances based on large-scale data; and conditioning the template instances based on medium-scale data; and wherein conditioning the template instances based on the smaller-scale data comprises conditioning the template instances based on fine-scale data.

Embodiment 5: The method of any of embodiments 1-4, wherein the template instances comprise multiple lobe/channel complex template instances.

Embodiment 6: The method of any of embodiments 1-5, wherein the template instances comprise one or more smaller scale template instances.

Embodiment 7: The method of any of embodiments 1-6, wherein conditioning comprises: conditioning the multiple lobe/channel complex template instances based on the large-scale data; thereafter conditioning the multiple lobe/channel complex template instances based on the medium-scale data; and thereafter conditioning the multiple lobe/channel complex template instances based on fine-scale data.

Embodiment 8: The method of any of embodiments 1-7, wherein the large-scale data comprises at least one of up-scaled well log or upscaled seismic data in order to model large-scale features.

Embodiment 9: The method of any of embodiments 1-8, wherein the large-scale data comprises net versus non-net data and trend constraints based on analysis of at least one of the well log or the seismic data.

Embodiment 10: The method of any of embodiments 1-9, wherein the medium-scale data is generated based on well log and seismic data indicative of sub-EoD (Environment of Deposition) constraints.

Embodiment 11: The method of any of embodiments 1-10, wherein the fine-scale data comprise at least one of well log data, seismic data, or core data.

Embodiment 12: The method of any of embodiments 1-11, wherein the one or more geological models comprises one or more reservoir models of a subsurface reservoir.

Embodiment 13: The method of any of embodiments 1-12, wherein the template instances comprise multiple lobe/channel complex template instances; and wherein generating the multiple lobe/channel complex template instances for the respective sub-zone is based on one or more lobe/channel complex templates generated by machine learning.

Embodiment 14: The method of any of embodiments 1-13, wherein conditioning the template instances based on large-scale data is at a complex set level; wherein conditioning the template instances based on medium-scale data is at a complex level; and wherein the template instances comprise one or more complex template instances.

Embodiment 15: The method of any of embodiments 1-14, wherein conditioning the template instances based on large-scale data is at a complex set level; wherein conditioning the template instances based on medium-scale data is at a complex level; and wherein the template instances comprise one or more complex set template instances.

Embodiment 16: The method of any of embodiments 1-15, wherein conditioning the template instances based on large-scale data is at a complex set level; wherein conditioning the template instances based on medium-scale data is at a complex level; and wherein the template instances comprise at least one complex template instance and at least one complex set template instance.

Embodiment 17: The method of any of embodiments 1-16, wherein conditioning the template instances based on the large-scale data modifies configuration geometry, location and properties of the template instances; wherein conditioning the template instances based on the medium-scale data modifies at least one of the configuration geometry, the location or the properties of the template instances; and wherein conditioning the template instances based on the fine-scale data modifies the configuration geometry, the location and the properties of the template instances.

Embodiment 18: A non-transitory computer readable medium having stored thereon software instructions that, when executed by a processor, cause the processor to perform the method of any of embodiments 1-17.

Embodiment 19: A system comprising a processor and a memory, the processor in communication with the memory, the memory having stored thereon software instructions that, when executed by the processor, cause the processor to perform the method of any of embodiments 1-17.

Embodiment 20: A computer-implemented method for generating and using a complex template, the method comprising: accessing one or more geological constraints; parameterizing, using the one or more geological constraints, a template in order to generate the complex template that is geologically feasible; and using the complex template in order to generate a reservoir model.

Embodiment 21: The method of embodiment 20: wherein the complex template comprises a lobe/channel complex template; and wherein parameterizing the template includes using a functional form model to parameterize at a lobe/channel complex level.

Embodiment 22: The method of any of embodiments 20 or 21, wherein parameterizing is via unsupervised learning for training an encoder.

Embodiment 23: The method of any of embodiments 20-22, wherein parameterizing the template comprises using training data from the functional form model of channel/lobes; and wherein supervised learning is employed to build geological realism and other geological considerations into the training.

Embodiment 24: The method of any of embodiments 20-23, wherein parameterizing is based on machine learning.

Embodiment 25: The method of any of embodiments 20-24, wherein parameterizing is via supervised learning for training a neural network.

Embodiment 26: The method of any of embodiments 20-25, wherein parameterizing is via deep learning.

Embodiment 27: The method of any of embodiments 20-26, wherein parameterizing the template is using statistical generative modeling.

Embodiment 28: The method of any of embodiments 20-27, wherein one or more generative adversarial networks are used for template parameterization.

Embodiment 29: The method of any of embodiments 20-29, wherein the template comprises an at least 3-dimensional tensor.

Embodiment 30: The method of any of embodiments 20-29, wherein the at least 3-dimensional tensor comprises at least a lobe/channel layer dimension including properties associated with a lobe/channel layer, a lobe/channel complex layer dimension including properties associated with a lobe/channel complex layer, and a lobe/channel layer complex set dimension including properties associated with a lobe/channel complex set layer.

Embodiment 31: A non-transitory computer readable medium having stored thereon software instructions that, when executed by a processor, cause the processor to perform the method of any of embodiments 20-30.

Embodiment 32: A system comprising a processor and a memory, the processor in communication with the memory, the memory having stored thereon software instructions that, when executed by the processor, cause the processor to perform the method of any of embodiments 20-30.

### REFERENCES

The following references are hereby incorporated by reference herein in their entirety, to the extend their disclosures are consistent with and support the claimed invention:
Emilien Dupont, Tuanfeng Zhang, Peter Tilke, Lin Liang, William Bailey, “Generating Realistic Geology Conditioned on Physical Measurements with Generative Adversarial Networks,” arXiv: 1802.03065v3, 2018.
Lukas Mosser, Olivier Dubrule, Martin J. Blunt, “Conditioning of three-dimensional generative adversarial networks for pore and reservoir-scale models,” arXiv:1802.05622, 2018.
Shing Chan, Ahmed H. Elsheikh, “Exemplar-based synthesis of geology using kernel discrepancies and generative neural networks,” arXiv preprint arXiv:1809.07748, 2018.
Shing Chan, Ahmed H. Elsheikh, “Parametrization of stochastic inputs using generative adversarial networks with application in geology,” arXiv preprint arXiv:1904.03677, 2019.
Xiuli Gai, Xiao-Hui Wu, Bogdan Varban, Kathryn Sementelli, Gregory Robertson, “Concept-Based Geologic Modeling Using Function Form Representation”, Society of Petroleum Engineers, SPE-161795-MS, pg. 2678-2690, Abu Dhabi International Petroleum Conference and Exhibition (2012).
James K. Miller, Tao Sun, Hong-Mei Li, Jonathon Stewart, Coralie Genty, Dachang Li, Colin Lyttle, “Direct Modeling of Reservoirs through Forward Process-based Models: Can We Get There?”, International Petroleum Technology Conference, IPTC 2008, DO 10.2523/12729-MS (2008).

1. A computer-implemented method for generating one or more a geological models for a subsurface, the method comprising:
for a defined volume of the subsurface:
generating template instances for the defined volume;
conditioning the template instances based on larger-scale data; and
separately conditioning the template instances based on smaller-scale data.

2. The method of claim 1, further comprising dividing one or more geological zones into a plurality of sub-zones; and
for a respective sub-zone of the plurality of sub-zones:
generating the template instances for the respective sub-zone;
conditioning the template instances based on the larger-scale data; and
separately conditioning the template instances based on the smaller-scale data.

3. The method of claim 1, wherein conditioning the template instances based on the larger-scale data comprises conditioning the templates instances based on at least one of large-scale data or medium-scale data; and
wherein conditioning the template instances based on the smaller-scale data comprises conditioning the template instances based on fine-scale data.

4. The method of claim 1, wherein conditioning the template instances based on larger-scale data comprises:
conditioning the template instances based on large-scale data; and
conditioning the template instances based on medium-scale data; and
wherein conditioning the template instances based on the smaller-scale data comprises conditioning the template instances based on fine-scale data.

5. The method of claim 1, wherein the template instances comprise multiple lobe/channel complex template instances.

6. The method of claim 1, wherein the template instances comprise one or more smaller scale template instances.

7. The method of claim 1, wherein conditioning comprises:
conditioning the multiple lobe/channel complex template instances based on the large-scale data;
thereafter conditioning the multiple lobe/channel complex template instances based on the medium-scale data; and
thereafter conditioning the multiple lobe/channel complex template instances based on fine-scale data.

8. The method of claim 1, wherein the large-scale data comprises at least one of up-scaled well log or upscaled seismic data in order to model large-scale features.

9. The method of claim 1, wherein the large-scale data comprises net versus non-net data and trend constraints based on analysis of at least one of the well log or the seismic data.

10. The method of claim 1, wherein the medium-scale data is generated based on well log and seismic data indicative of sub-EoD (Environment of Deposition) constraints.

11. The method of claim 1, wherein the fine-scale data comprise at least one of well log data, seismic data, or core data.

12. The method of claim 1, wherein the one or more geological models comprises one or more reservoir models of a subsurface reservoir.

13. The method of claim 1, wherein the template instances comprise multiple lobe/channel complex template instances; and
wherein generating the multiple lobe/channel complex template instances for the respective sub-zone is based on one or more lobe/channel complex templates generated by machine learning.

14. The method of claim 1, wherein conditioning the template instances based on large-scale data is at a complex set level;
wherein conditioning the template instances based on medium-scale data is at a complex level; and
wherein the template instances comprise one or more complex template instances.

15. The method of claim 1, wherein conditioning the template instances based on large-scale data is at a complex set level;
wherein conditioning the template instances based on medium-scale data is at a complex level; and
wherein the template instances comprise one or more complex set template instances.

16. The method of claim 1, wherein conditioning the template instances based on large-scale data is at a complex set level;
wherein conditioning the template instances based on medium-scale data is at a complex level; and
wherein the template instances comprise at least one complex template instance and at least one complex set template instance.

17. The method of claim 1, wherein conditioning the template instances based on the large-scale data modifies configuration geometry, location and properties of the template instances;
wherein conditioning the template instances based on the medium-scale data modifies at least one of the configuration geometry, the location or the properties of the template instances; and
wherein conditioning the template instances based on the fine-scale data modifies the configuration geometry, the location and the properties of the template instances.

18. A computer-implemented method for generating and using a complex template, the method comprising:
accessing one or more geological constraints;
parameterizing, using the one or more geological constraints, a template in order to generate the complex template that is geologically feasible; and
using the complex template in order to generate a reservoir model.

19. The method of claim 18, wherein the complex template comprises a lobe/channel complex template; and
wherein parameterizing the template includes using a functional form model to parameterize at a lobe/channel complex level.

20. The method of claim 18, wherein parameterizing is via unsupervised learning for training an encoder.

21. The method of claim 18, wherein parameterizing the template comprises using training data from the functional form model of channel/lobes; and
wherein supervised learning is employed to build geological realism and other geological considerations into the training.

22. The method of claim 18, wherein parameterizing is based on machine learning.

23. The method of claim 18, wherein parameterizing is via supervised learning for training a neural network.

24. The method of claim 18, wherein parameterizing is via deep learning.

25. The method of claim 18, wherein parameterizing the template is using statistical generative modeling.

26.-30. (canceled)
